(19) United States
(12) Patent Application Publication
(10) Pub. No.: US 2005/0011756 A1
(43) Pub. Date: Jan. 20, 2005

(54) Sputtering system

(75) Inventors: Masahiro Shibamoto, Yokohama-shi (JP); Kazuto Yamanaka, Tokyo (JP); Naoki Watanabe, Tokyo (JP)

Correspondence Address: BURNS DOANE SWECKER & MATHIS L L P, POST OFFICE BOX 1404, ALEXANDRIA, VA, 22313-1404, US

(73) Assignee: ANELVA Corporation, Fuchu-shi (JP)

(21) Appl. No.: 10/852,148

(22) Filed: May 25, 2004

(30) Foreign Application Priority Data
May 26, 2003 (JP) 2003-147529

(51) Int. Cl. C23C 14/32

(52) U.S. Cl. 204/298.07; 204/298.16

(57) ABSTRACT

A sputtering system provided with a vacuum chamber into which a substrate is loaded, a cathode unit provided in the vacuum chamber so as to face the substrate and including a cathode with a target, a power source for supplying power to the cathode of the cathode unit, a vacuum evacuation system for evacuating the inside of the vacuum chamber to a vacuum, and a gas introduction mechanism for making reactive gas flow from a center of the cathode unit along the surface of the target to the outsides, wherein reactive gas fed from a reactive gas feed system flows from the center part of the cathode unit along the surface of the target to the outsides due to the center gas introduction mechanism.

### BACKGROUND OF THE INVENTION

1. Field of the Invention

The present invention relates to a sputtering system, and more particularly to a sputtering system using a reactive gas to deposit a film on a substrate by reactive sputtering.

2. Description of the Related Art

In a sputtering system, the material of a target attached to a cathode is stripped off by ions to form target material particles (sputter particles) which in turn are supplied onto substrate facing the target so as to form a thin film of the target material on the substrate. Therefore, in the sputtering system, the gas for causing sputtering in a vacuum chamber, such as a sputter gas or plasma generating gas, is introduced into a vacuum chamber, and the target is supplied with a high frequency power or supplied with a DC voltage. Thereby, in the vacuum chamber, required energy is given to generate plasma and ions for producing the sputter particles are produced. The sputter particles strike the surface of the substrate and the target material is deposited on the surface of the substrate.

In the above sputtering systems a reactive sputtering system has been known. In the reactive sputtering system, the vacuum chamber is filled with a reactive gas such as oxygen or nitrogen together with an inert gas (or sputter gas) such an argon (Ar) gas. In the reactive sputtering system, for example, the argon ions produced in the plasma strike the target material to strip off particles of the target material. The particles of the target material react with the reactive gas, and as a result the reaction product is deposited on the surface of the substrate to make a film thereon. If the concentration of the reactive gas is high, the reactive gas makes a compound layer on the surface of the target material. With the sputtering of the compound layer, a reaction product having a desired composition is deposited on the substrate.

On the other hand, for example, in order to form a magnetic recording medium on a substrate, it is necessary to form a multi-layer film on the substrate, which is formed by successively stacking various metal films, or oxide films or nitride films of metal material. In this magnetic recording medium, uniformity of thickness, quality, and uniformity of the magnetic characteristics etc. of the film are requested. In particular, in a hard disk etc., uniformity of the magnetic characteristics in the circumferential direction and radial direction of the substrate (in the case of a longitudinal recording medium), or uniformity of the magnetic characteristics in the perpendicular direction of the substrate (in the case of a perpendicular recording medium) is strongly requested.

When using the above-mentioned reactive sputtering system utilizing a reactive gas etc. to form a multilayer film on the substrate and create a magnetic recording medium, achievement of the desired uniformity of thickness and quality and uniformity of magnetic characteristics is difficult. Next, the basic configuration of the reactive sputtering system of the related art will be explained with reference to FIG. 16 and FIG. 17 so as to explain the problems.

FIG. 16 shows a vertical type reactive sputtering system. The walls of a vacuum chamber 101 of the reactive sputtering system are provided with, for example, at least cathodes 104 and 105 respectively provided with one target 102 and 103 and arranged facing each other in a coaxial state. A substrate 106 is arranged in a vertical state at a position of equal distances from the surfaces of the targets 102 and 103. The substrate 106 is held by a substrate support plate 107. The substrate 106 may be in a stationary state or a rotating state or may be in a moving state.

As the gas for generating the sputter plasma, in particular, in the case of reactive sputtering, a mixed gas 108 including an argon gas (Ar) and a reactive gas is introduced from a gas introduction part 109 at the ceiling of the vacuum chamber 101. The introduced mixed gas moves as shown by the arrows 110 and is exhausted from an exhaust part 111 at the floor. In this gas introduction method, the reactive gas is consumed mainly at the gas upstream region, so the reactive gas does not sufficiently reach the entire surfaces of the targets 102 and 103, the distributions of the concentration of the reactive gas on the target surfaces become uneven, and the characteristics of the reactive films deposited on the substrate 106 become uneven or are ruined.

FIG. 17 shows a horizontal type reactive sputtering system. In this reactive sputtering system, a cathode 122 provided with a single target 121 is arranged in a horizontal state on the floor of a vacuum chamber 101, while a substrate 123 is placed horizontally at a position a predetermined distance from the surface of the target 121. As the gas for producing the sputter plasma, the above mixed gas is introduced from a gas introduction part 124 at the left wall of the vacuum chamber 101 in the figure. The introduced mixed gas travels as shown by the arrows 125 and is exhausted from an exhaust part 126 at the right wall. In this reactive sputtering system as well, the reactive gas is consumed at the gas upstream region, so the reactive gas does not sufficiently reach the entire surface of the target 121, the distribution of the concentration of the reactive gas on the target surface becomes uneven, and the characteristics of the reactive film deposited on the substrate 123 become uneven or are ruined.

As explained above, in a sputtering system forming a film by sputtering while introducing a reactive gas into a vacuum chamber to create a flow of reactive gas, the reactive gas is consumed at the upstream part of the flow of the reactive gas, the reactive gas does not sufficiently reach the entire surface of the target, the distribution of the concentration of the reactive gas on the target surface becomes uneven, and the characteristics of the reactive film deposited on the substrate become uneven.

Therefore, to solve this problem in a reactive sputtering system, in the related art, several proposals have been made as outlined below.

Japanese Patent Publication (A) No. 5-320891 discloses a sputtering system according to which, in a first aspect of the invention, the target material is formed with a plurality of small holes to which gas introduction pipes are connected and, in a second aspect of the invention, insertion members are provided to divide the target material and the insertion members are formed with a plurality of small holes to which gas introduction pipes are connected. Due to these structures, sputter gas including reactive gas is introduced toward the substrate facing the target. Japanese Patent Publication (A) No. 2001-337437 discloses a target structure in which the target material is formed with a plurality of small holes and sputter gas including the reactive gas is introduced toward the substrate facing the target. Japanese Patent Publication (A) No. 2002-269858 discloses a sputtering system in which an inner circumferential mask covering the inner circumference of a substrate is formed with gas introduction paths and gas blowing ports and the gas introduction paths etc. are utilized to introduce the reactive gas to the surface of a substrate. Japanese Patent Publication (A) No. 5-148634 discloses a sputtering system in which argon gas and a reactive gas are introduced to a target by a gas pipe positioned at the outer circumference and a gas pipe positioned at the inner circumference. Japanese Patent Publication (A) No. 10-280139 discloses a sputtering system in which gas for producing the plasma is introduced from a gas blowing passage arranged at the circumference of the target.

In each of the systems of Japanese Patent Publication (A) No. 5-320891, Japanese Patent Publication (A) No. 2001-337437, Japanese Patent Publication (A) No. 5-148634, and Japanese Patent Publication (A) No. 10-280139, sometimes a sufficient uniformity of the reactive gas cannot be obtained depending on the exhaust state. The system of Japanese Patent Publication (A) No. 2002-269858 is provided with a gas introduction part at a structural part of the substrate holder facing the target, so movement of the substrate holder is difficult. Further, the inner circumference mask is moved each time a substrate is detached and attached, so generates dust. The problem therefore arises of a shorter maintenance cycle.

While various means have been devised in the related art as explained above so as to enable the deposition of a film of a uniform quality on a substrate surface, the above problems have not been completely solved. These means are therefore insufficient. Obtaining uniform properties of the reactive film is extremely difficult. In particular, in a magnetic recording medium, deterioration of the longitudinal distribution of the film properties is caused due to the change in composition of the reaction film such as the nitride film of the multilayer film structure and has a major effect on the magnetic properties of the medium.

### OBJECTS AND SUMMARY

An object of the present invention is to provide a sputtering system which introduces a sputter gas and reactive gas into the vacuum chamber and forms a film by reactive sputtering wherein the concentration of the reactive gas flowing along the surface of the target is made substantially uniform to raise the uniformity of the reaction between the reactive gas and target and therefore enable greater uniformity of the thickness, quality, and properties of the film.

The sputtering system according to a first aspect of the invention is a sputtering system arranging a cathode provided with a target so as to face a substrate and sputtering the target by reactive sputtering so as to deposit a film on the substrate and is provided with a gas introduction mechanism (center gas introduction mechanism) for making at least the reactive gas flow from the center of a cathode unit along the surface of the target to the outsides. More particularly, it is provided with a vacuum chamber into which a substrate is loaded, at least one cathode unit provided in the vacuum chamber so as to face the substrate and including a cathode with a target, a power source for supplying power to the cathode of the cathode unit, a vacuum evacuation system for evacuating the inside of the vacuum chamber to a vacuum, and a gas introduction mechanism for making reactive gas flow from a center of the cathode unit along the surface of the target to the outsides.

In the above configuration, the flow of gas is kept from dispersing in the inside of the vacuum chamber as a whole and a path of flow is formed near the surface of the target. It therefore becomes possible to obtain a uniform concentration of at least the reactive gas at the surface of the target.

Preferably, the cathode unit is structured with one target attached to one cathode in a coaxial relationship and the reactive gas flows from a center of the target toward the outer circumference of the target along the surface of,the target.

Alternatively, the cathode unit is structured with a plurality of cathode sets each comprised of a cathode and target and the plurality of cathode sets are arranged off-axis around the center of the cathode unit.

The sputtering system according to a second aspect of the present invention is a sputtering system which arranges cathodes provided with targets to face a substrate and sputters the target by reactive sputtering to deposit a film on the substrate. It is provided with a cathode unit structured provided with a plurality of cathode sets each comprised of a cathode and target. The plurality of cathode sets are arranged off-axis around the center of the cathode unit. A gas introduction mechanism is provided for making at least reactive gas flow from a center of each cathode set toward its periphery along the surface of said target. More specifically, it is provided with a vacuum chamber into which a substrate is loaded, a cathode unit provided in the vacuum chamber so as to face the substrate and structured provided with a plurality of cathode sets each comprised of a cathode and a target, a power source for supplying power to the cathodes of the cathode unit, and a vacuum evacuation system for evacuating the inside of the vacuum chamber to a vacuum.

Preferably, the gas introduction mechanism includes an introduction hole for introducing the reactive gas and a gas dispersion member for dispersing the introduced reactive gas.

Preferably, the system is further provided with a covering member surrounding a target and having a part opening toward the substrate.

Preferably, the system is further provided with a passage selecting unit (vane member) for selectively passing target material particles moving from a target to the substrate.

More preferably, the passage selecting unit is provided between the target and the substrate to be able to rotate in a coaxial relationship with the substrate.

Preferably, the system is further provided with, along with the gas introduction mechanism for making the reactive gas flow along the surface of a target toward the outside, another gas introduction mechanism for making reactive gas flow from the outer circumference of a cathode along the surface of the target toward the inside. Due to this configuration, it is possible to obtain a uniform concentration of the reactive gas at the surface of a target more effectively without regard as to the position of arrangement of the exhaust port.

Note that the sputtering system according to the present invention can also be configured with a plurality of targets attached around the center of a cathode and with the centers of the targets rotating around a circle coaxial with the center of the cathode.

The present invention preferably gives the following effects: It provides a system for sputtering for forming a film on a substrate, in particular for sputtering a target by reactive sputtering to deposit a film on a substrate, wherein a gas introduction mechanism is provided for making at least the reactive gas flow from the center of a cathode unit along the surface of a target toward the outsides and therefore the concentration of the reactive gas becomes substantially uniform over the entire surface of the target and the thickness, quality, and properties of the film deposited on the substrate can be made uniform.

Further, since at least the reactive gas is introduced from a gas introduction mechanism provided at the position of the center of a cathode (the center of the target when the cathode and target are in a coaxial positional relationship) and a flow of gas along the surface of the target is formed, the concentration of the reactive gas becomes uniform over the entire surface of the target and as a result the thickness, quality, and properties of the film deposited on the substrate can be made uniform.

Further, since a covering member is provided, the flow of reactive gas over the surface of a target can be made close to the surface of the target and follow along the surface of the target.

Further, since a passage selecting unit is provided for selectively passing the target material particles traveling from a target to the substrate and the passage selecting unit is made to rotate, it is possible to make the flow of reactive gas be close to the surface of the target and follow along the surface of the target and therefore form a more uniform concentration of reactive gas at the target surface.

Further, since an outer circumference gas introduction mechanism is provided to introduce reactive gas from the outer circumference of a target as well, the concentration of reactive gas at the target surface can be made more uniform.

Due to the above, the properties of the reactive film formed on the substrate become more uniform, the variations in magnetic properties of a magnetic recording medium comprised of a multilayer film using this can be reduced, and the yield of the production process of the media can be improved.

### BRIEF DESCRIPTION OF THE DRAWINGS

These and other objects and features of the present invention will become clearer from the following description of the preferred embodiments given with reference to the attached drawings, wherein:

FIG. 1 is a horizontal sectional view of a vacuum chamber showing the general configuration of a sputtering system according to an embodiment of the present invention;

FIG. 2 is a sectional view along the line A-A in FIG. 1;

FIG. 3 is a view similar to FIG. 2 showing the principal configuration of a sputtering system according to a first embodiment of the present invention;

FIG. 4 is a perspective view in the direction B in FIG. 3;

FIG. 5 is a view similar to FIG. 2 showing the principal configuration of a sputtering system according to a second embodiment of the present invention;

FIG. 6 is a perspective view in the direction B in FIG. 5;

FIG. 7 is a perspective view of a vane member;

FIG. 8 is a view similar to FIG. 2 showing the principal configuration of a sputtering system according to a third embodiment of the present invention;

FIG. 9 is a front view of the relationship between a cathode, target, and vane member in the configuration of the third embodiment;

FIG. 10A shows the principal configuration of a first modification of the third embodiment and is a front view of a cathode unit;

FIG. 10B is a vertical sectional view of the characterizing configuration of the first modification of the third embodiment;

FIG. 11A shows the principal configuration of a second modification of the third embodiment and is a front view of a cathode unit;

FIG. 11B is a sectional view along the line D-D of FIG. 11A;

FIG. 12A shows the principal configuration of a third modification of the third embodiment and is a front view of a cathode unit;

FIG. 12B is a sectional view along the line E-E of FIG. 12A;

FIG. 13 is a vertical sectional view of the principal configuration of a sputtering system according to a fourth embodiment of the present invention;

FIG. 14 is a vertical sectional view of the principal configuration of a sputtering system according to a fifth embodiment of the present invention;

FIG. 15A is a vertical sectional view for explaining a first example of the method of flow of a gas in a reactive gas introduction mechanism;

FIG. 15B is a vertical sectional view for explaining a second example of the method of flow of a gas in a reactive gas introduction mechanism;

FIG. 16 is a horizontal sectional view of a sputtering system of the related art; and

FIG. 17 is a vertical sectional view of another sputtering system of the related art.

### DETAILED DESCRIPTION OF THE PREFERRED EMBODIMENTS

Preferred embodiments of the present invention will be described in detail below while referring to the attached figures.

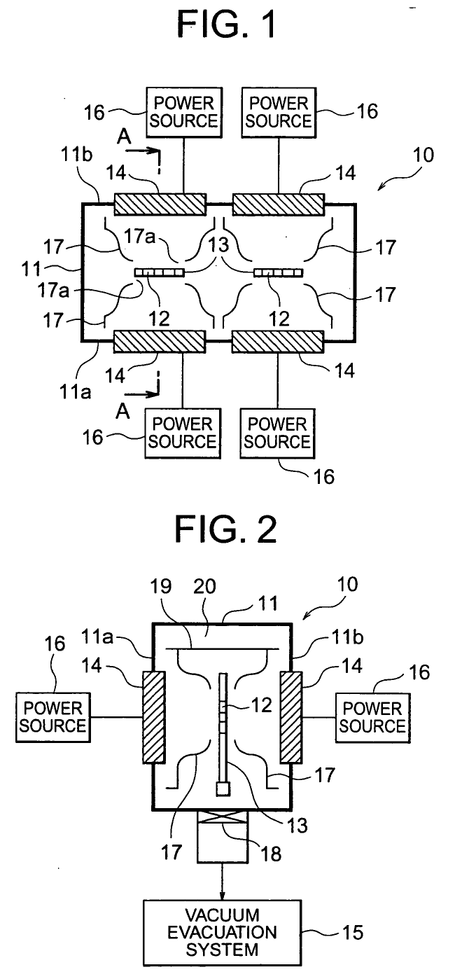

An exemplary structure of a vacuum chamber of a sputtering system according to the present invention will be explained in brief first based on FIG. 1 and FIG. 2. The sputtering system is a vertical reactive sputtering system. Note that in FIG. 1 and FIG. 2, the wall part etc. of the vacuum chamber are illustrated generally by simple lines.

In the sputtering system 10, substrates 12 on which films are to be formed are arranged in vertical states inside the vacuum chamber 11. The substrates 12 are preferably arranged so that their two surfaces are vertical. The substrates 12 are for example ring shapes formed overall as thin disks with holes at their centers. Substrates 12 arranged in the vertical state, as shown in FIG. 2, are kept in their vertical postures by substrate support plates (substrate holders) 13 arranged vertically. The substrate support plates 13 or substrates 12 may be in a stationary state or a rotating state or a state able to move while being transported by a rail transport mechanism at their bottoms.

As shown in FIG. 2, left and right side walls 11a and 11b positioned at the two sides of the substrates 12 are provided with cathode units 14 in vertical states.

In FIG. 1 and FIG. 2, the cathode units 14 are shown by hatched blocks. In FIG. 2, when forming films at the two surfaces of the substrates 12, the inside space (vacuum chamber) of the vacuum chamber 11 is evacuated to a required vacuum by a vacuum exhaust system 15 for evacuation from for example the floor part. Further, the substrates 12 on which the films are to be formed are held at the positions shown in FIG. 1 and FIG. 2 by substrate support plates 13.

Here, the actual structure of a “cathode unit” will be explained. A “cathode unit” includes one or more cathodes and attaches a target to the vacuum chamber side surface of each cathode. In principle, one cathode has one target attached to it. The set of one cathode and one target will be referred to as a “cathode set” in this specification. In a cathode set, the target and cathode are in a coaxial positional relationship and therefore the center of the target and the center of the cathode are in register.

When the cathode unit 14 includes a single cathode, that cathode is provided with a single target in a coaxial positional relationship and therefore one cathode set is included. In this example of the configuration, the center of the target, the center of the cathode, and the center of the cathode set are all in register.

Further, when the cathode unit 14 includes for example three cathodes, each of the three cathodes is provided with a single target in a coaxial positional relationship and therefore three cathode sets are arranged offset in position by angles of 120 degrees on a for example disk shaped mounting member. In this example of the configuration, the centers of the targets and the centers of the cathodes of the cathode sets are in register, but are offset in position in positional relationship with the center of the cathode unit.

Note that a cathode unit 14 is shaped overall as a disk shape or ring shape and has an axial center.

The inside of the vacuum chamber 11 of the above reactive sputtering system 10 is filled with argon (Ar) or another inert gas for sputtering (sputter gas or plasma generating gas) and oxygen, nitrogen, or another reactive gas so as to form a plasma for sputtering the targets. The inert gas and reactive gas may be introduced together as a mixed gas or may be introduced independently separately. The configuration of the gas introduction mechanism is suitably selected in accordance with the method of introduction. In FIG. 1 and FIG. 2, illustration of the gas introduction mechanism is omitted. Further, each cathode unit 14 is connected to a power source 16 for supplying predetermined voltage to the cathodes for sputtering of the target. Usually, a power source 16 is provided for each target, that is, for each cathode.

According to FIG. 1, for example two substrates 12 are arranged in the vacuum chamber 11. By providing cathode units 14 at positions to the left and right of the two substrates, a total of four cathode units 14 are provided in the chamber as a whole. The substrates 12 are arranged at substantially the same distances from the left and right cathode units 14. The substrates 12 and the left and right cathode units 14 are provided between them with covering members 17 covering the targets of the cathode units 14 and having openings 17a at parts facing the surfaces of the substrates 12. The covering members are illustrated by line drawings, but for example are ring-shaped members similar to shallow bottom pans or dishes.

The inside of the vacuum chamber 11 of the sputtering system 10 is filled with Ar etc. and a reactive gas for sputtering as explained above. In the present invention, the method of introducing the reactive gas is important in relation to the targets in the vacuum chamber 11, so in this embodiment, the gas introduction mechanism for the reactive gas and the method of introduction of the reactive gas (the method of flow or method of blowing the reactive gas in the vacuum chamber) will be explained in detail below. In this embodiment, a configuration where the reactive gas and the sputter gas are introduced mixed together is assumed. Therefore, the flow of the reactive gas and the flow of the sputter gas in the vacuum chamber 11 are the same. In the following explanation, the explanation will be given focusing on the introduction and flow of the reactive gas. Note that it is also possible to provide another gas introduction mechanism and introduce the reactive gas separately from the sputter gas.

To evacuate the inside of the vacuum chamber 11 to a required vacuum or to exhaust the gas introduced into the vacuum chamber 11 outside of the vacuum chamber, as shown in FIG. 2, a vacuum evacuation system 15 is provided under the vacuum chamber 11. The vacuum evacuation system 15 evacuates the inside of the vacuum chamber or exhausts the gas through a valve 18 provided at the floor of the vacuum chamber 11. The vacuum chamber 11 of this sputtering system 10 is structured to draw out the gas from the bottom. Further, as shown in FIG. 2, each covering member 17 is provided above it with a horizontal inside wall 19, whereby a space 20 for escape of gas introduced into the vacuum chamber is formed. In the illustrated example, each covering member 17 is fixed to an inside wall 19.

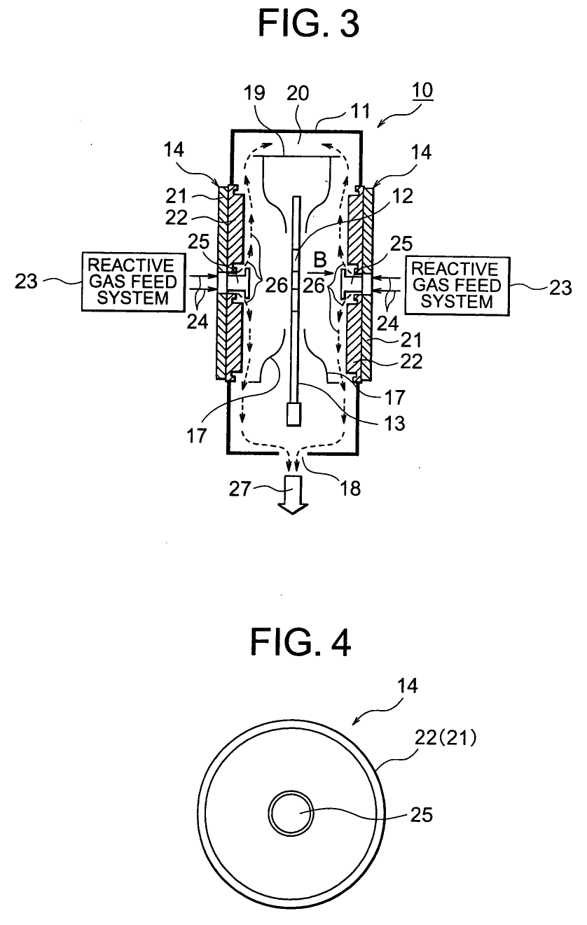

Next, a first embodiment of the present invention relating to the vacuum chamber 11 of a sputtering system 10 having the above structure will be explained with reference to FIG. 3 and FIG. 4. FIG. 3 is a sectional view along the line A-A in the same way as FIG. 2 and shows the more detailed structure for a specific system. FIG. 3 shows the detailed structure of the parts of the cathode units 14 and the method of introduction and flow of the reactive gas. FIG. 4 is a perspective view in the direction B in FIG. 3 and shows parts of a cathode unit 14, that is, the front shapes of the cathode and target. In FIG. 3, elements substantially the same as elements explained in FIG. 1 and FIG. 2 are assigned the same notations.

In FIG. 3, a target 22 is attached to the front surface of the vacuum chamber side of the cathode 21 of each cathode unit 14. As shown in FIG. 4, the cathode 21 and the target 22 are substantially the same in shape, for example, have ring shapes, and are formed with holes at their centers. Each target 22 is fixed to a cathode 21 in a coaxial positional relationship. Each cathode 21 is supplied with a required voltage as explained in FIG. 2 etc. Further, in this embodiment, each cathode 21 and target 22 are fixed to a side wall of the vacuum chamber 11.

The center hole of each cathode 21 and the center hole of each target 22 are connected to a reactive gas feed system 23 (for introducing a mixed gas with argon gas or another sputter gas, hereinafter referred to as a “reactive gas feed system”) through a not shown gas pipe. In FIG. 3, the arrows 24 show the flow of reactive gas fed from reactive gas feed system 23 to the inside of the vacuum chamber 11.

In the vacuum chamber 11, a part for introduction of the reactive gas (blowing part) constituted by the reactive gas introduction mechanism is provided at the center of each target. This reaction gas introduction mechanism is comprised of the center holes (gas introduction holes) of the coaxial cathode 21 and target 22, a gas dispersion member 25 arranged at a position coaxial with the target 22, and a gas introduction port formed between the gas dispersion member 25 and the inner surface of the center hole of the target 22.

The gas dispersion member 25 is arranged at a distance from the target 22 of an extent not causing electrodischarge, for example, a gap of about 2 to 3 mm. In FIG. 3, the gas dispersion member 25 is arranged fixed by a not shown fixing member for example. However, the arrangement of the gas dispersion member 25 is not limited to a fixed arrangement. The gas dispersion member 25 is provided with a small diameter shaft and a large diameter dispersion part (enlarged diameter part). The dispersion part of the gas dispersion member 25 is provided in a positional relationship blocking the wide part of the inside opening of the center hole of the target 22. The gap between the gas dispersion member 25 and the inside surface of the center hole of the target 22 forms a passage for flow of the reactive gas. Gas introduced from the gas introduction port around the gas dispersion member 25 strikes the dispersion part of the gas dispersion member 25 to be blown out to the sides changed in direction and flows evenly from the center to the outer circumference (peripheral edges) along the surface of the target 2 as shown by the arrows 26.

In the state with the reactive gas blown out evenly along the surface of the target 22 in this way, a not shown high frequency or DC voltage is applied to the cathode 21 to cause the generation of plasma. Due to this, sputter particles (target material particles) sputtered from the target 22 react with the reactive gas, whereby a desired reactive film is deposited on the substrate 12.

When separately introducing argon gas or another sputter gas and the reactive gas, the reactive gas is introduced from the reactive gas feed system 23 at the center of a cathode or target as explained above, but the sputter gas may also be introduced from any other part of the vacuum chamber. For example, it may be introduced from above the vacuum chamber or from the outer circumference of the cathode or target. Further, as explained later, the gas introduced from the outer circumference of the cathode or target may be made a mixed gas with a reactive gas.

In the above, preferably a main flow of gas (26) is formed near the surface of the target 22 facing each substrate 12 and is kept from dispersing to the substrate 12 side by making the top (dispersion part) of the gas dispersion member 25 stick out to the inside of the vacuum chamber from the plane including the surface of the target 22. Further, preferably the head is made large in diameter and is formed as an enlarged diameter part as explained above.

Each target 22 is surrounded by a covering member 17. The size of the covering member 17 and the distances between the covering member 17 and the target 22 and substrate 12 are suitably set so that mainly a flow of gas near the surface of the target 22 and a flow of gas from near the surface are effectively formed and exhausted. In FIG. 3, the reactive gas introduced from the introduction mechanism to the inside of the vacuum chamber through the reactive gas introduction mechanism, as shown by the arrows 26, flows above to the space 20 and is exhausted below to the outside of the vacuum chamber as shown by the arrows 27 through the hole part corresponding to the valve 18.

In the above configuration using covering members 17, it is possible to prevent sputter particles from traveling to other locations in the vacuum chamber, but synergistically it is possible to effectively form a flow of reactive gas near the surface of each target.

Note that the top of the gas dispersion member 25 does not necessarily have to stick out from the plane including the surface of each target 22.

According to the first embodiment, a reactive gas introduction mechanism can be used to form an even flow of the reactive gas along the surface of a target 22 from its center to the outer circumference as shown by the arrows 26, so the concentration of the reactive gas flowing along the surface of the target can be made uniform, the uniformity of the reaction between the reactive gas and target can be made uniform, the uniformity of the reaction between the reactive gas and the target is improved, and the thickness, quality, and characteristics of the film deposited on each substrate 12 can be made uniform.

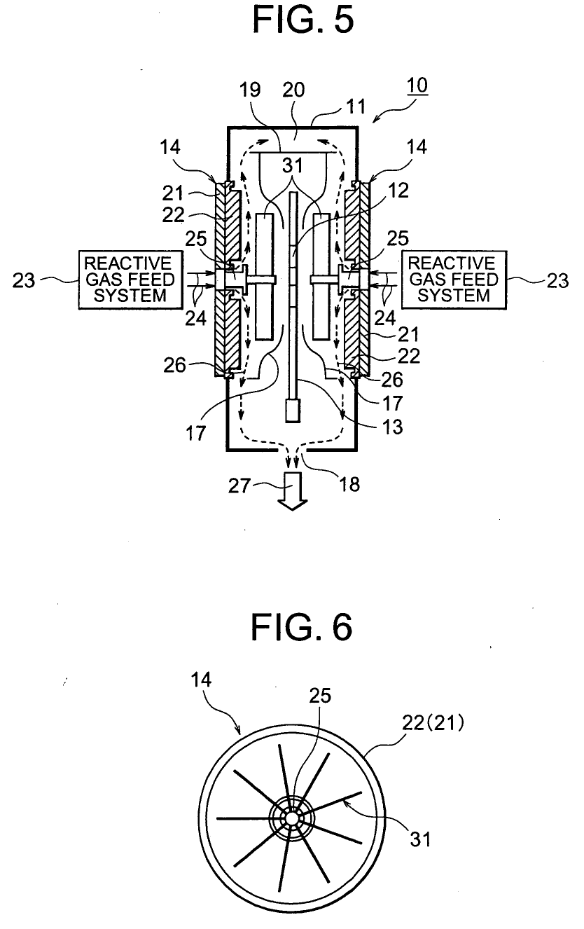

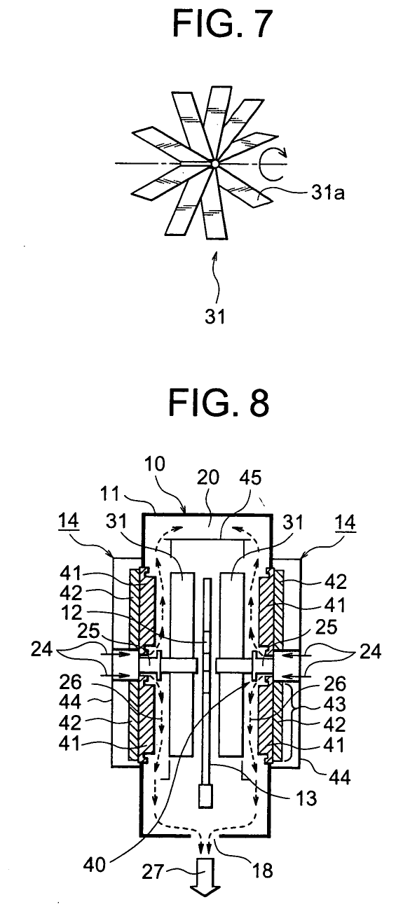

A sputtering system according to a second embodiment of the present invention is shown below in FIG. 5 to FIG. 7. If a vane member 31 having a plurality of (for example, nine) vanes 31 a extending in a radial manner at equal intervals as shown in FIG. 7 is coaxially and rotatably attached to a cylindrical gas dispersion member 25 of the reactive gas introduction mechanism and that vane member 31 is made to rotate, the concentration of the reactive gas over the surface of the target can be made uniform more effectively and a uniform reactive film can be formed on the substrate. FIG. 5 is a view similar to FIG. 3 of a sputtering system with the vane member 31 attached, while FIG. 6 is a view similar to FIG. 4 of a sputtering system with the vane member 31 attached. In FIG. 5 and FIG. 6, elements substantially the same as elements explained in the first embodiment are assigned the same notations and detailed explanations are omitted.

In the above, the gas dispersion member 25 shown in FIG. 3 was formed by for example a solid member and was provided fixed in place. As opposed to this, the gas dispersion member 25 shown in FIG. 5 is formed by a hollow member having a cylindrical shaft and fixed in place so as to allow passage of the shaft of the vane member 31. Further, the gas dispersion member 25 can be provided so as to be able to be rotated by a not shown rotation drive mechanism and the top of the gas dispersion member 25 may be provided with the vane member 31 fixed in place by welding etc. in a projecting state. With this configuration, the two members are together rotatable. Note that in this case, it is also possible to provide the vane member 31 at the top of the gas dispersion member 25 in a detachable manner. When detaching the vane member 31, the gas dispersion member 25 is preferably used held in a state not allowing rotation.

The vane member 31 is driven to rotate by being linked with a rotational gear mechanism provided outside of the vacuum chamber 11. Further, the vane member 31 can be either independent of or integral with the reactive gas introduction mechanism and can freely rotate. The vane member 31 is a means for selectively passing target member particles traveling from a target to the substrate. A plurality of axially symmetric open regions are formed by the spaces formed between the vanes. The detailed configuration of the vane member 31 is disclosed in for example Japanese Patent Application No. 2001-262108 (Japanese Patent Publication (A) No. 2003-73825) of the same assignee as the present invention.

If utilizing a sputtering system having the configuration of the first or second embodiment to deposit a nitride film of a CrNb alloy, a Cr alloy, a Co-based film, and a protective film on a glass substrate to prepare a longitudinal magnetic recording medium, the Hc, one of the magnetic properties, of the longitudinal magnetic recording medium becomes ±2.5%. As opposed to this, if utilizing the conventional system of FIG. 12 to produce a magnetic recording medium of the same film configuration, the Hc becomes ±45.7%. Therefore, the present invention enables a great improvement. This is believed due to the fact that the concentration of nitrogen gas over the CrNb target surface becomes uniform and therefore the quality of the CrNb nitride film in the multilayer film configuration becomes uniform and the magnetic properties of the device are improved.

The sputtering system according to the present embodiment can be used for both “longitudinal” and “perpendicular” magnetic recording media depending on the provision of the vane member 31. Note that the invention is not however limited to a magnetic recording medium and can of course also be applied to production of an ordinary reactive sputter film.

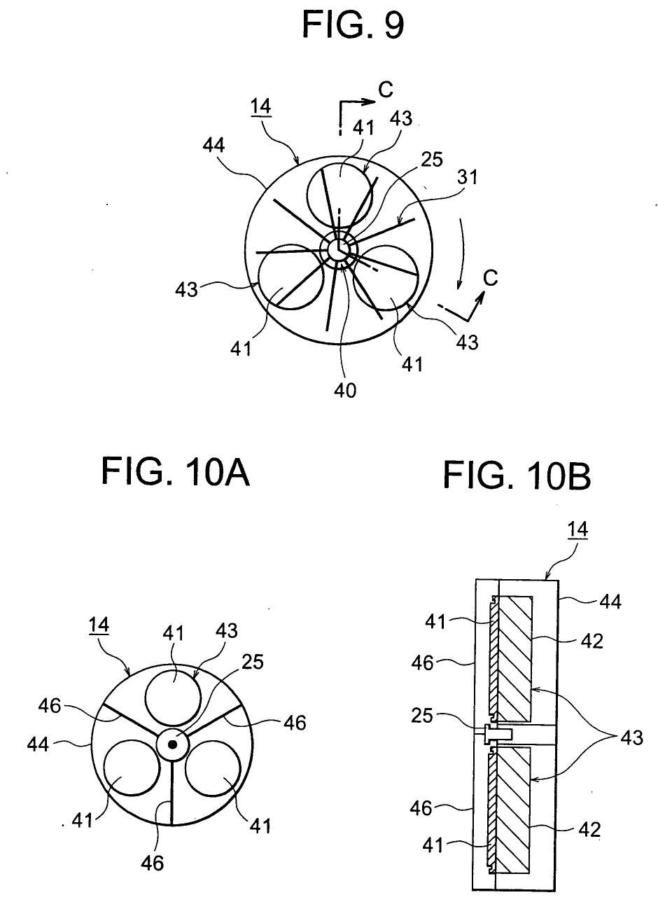

Next, a third embodiment of a sputtering system according to the present invention will be explained with reference to FIG. 8 and FIG. 9. FIG. 8 corresponds to the above FIG. 3, while FIG. 9 corresponds to the above FIG. 4 in relation to the part of the cathode unit. Note that a sectional view of the part of the cathode unit in FIG. 8 is given by the sectional view along the line C-C in FIG. 9. Note that in FIG. 8 and FIG. 9, elements substantially the same as elements explained in the first or second embodiment are assigned the same notations.

In the third embodiment, a plurality of targets 41 are arranged in an off-axis relationship from the shaft (center part) 40. For example, as shown in FIG. 9, three targets 41 having disk shapes are attached. At the back sides of the three targets 41, cathodes 42 having substantially the same diameters as the targets 41 are provided. The cathode sets 43 comprised of the targets 41 and the cathodes 42 are preferably fixed to a disk shaped mounting member 44. In the disk shaped mounting member 44, as shown in FIG. 9, the three cathode sets 43 are arranged around the center part 40 of the mounting member 44 at angular intervals of for example 120 degrees. In FIG. 9, only the arrangement of the targets 41 at the disk shaped mounting member 44 is shown. Each of the three targets 41 is attached with its center part offset from the center part 40 of the mounting member 44, that is, in an off-axis state.

A cathode unit 14 of the third embodiment is comprised of three cathode sets 43 and the disk shaped mounting member 44 to which these are fixed based on the above positional relationship.

In this embodiment, the reactive gas, as shown by the arrows 24, is introduced through a hole formed at the center part of the cathode unit 14 and, as shown by the arrows 26, flows from the center part of the cathode unit 14 toward the outer periphery of the cathode unit 14 in the radial direction.

In this embodiment, by making the mounting member 44, that is, the cathode unit as a whole, a rotatable structure, the three targets 41 are made to rotate around the center part 40. In FIG. 8, illustration of the mechanism for rotating the disk shaped mounting member 44 is omitted, but one example of this mechanism is disclosed in Japanese Patent Application No. 2000-278962 of the same assignee as this application.

Further, in this embodiment as well, the above-mentioned vane member 31 is provided. In the case of this embodiment, the vane member 31 is fixed projecting out at the top of the gas dispersion member 25. The gas dispersion member 25 and the vane member 31 are made to rotate by a not shown rotation drive mechanism.

The shaft 40 of the disk shaped mounting member 44, that is, the cathode unit 14, is provided with the above-mentioned gas introduction mechanism for the reactive gas. The gas introduction mechanism is configured by an introduction hole for introducing the reactive gas and a gas dispersion member 25. The above covering member 17 may also be omitted and, instead, a top inner wall 45 forming a space 20 may be provided. Note that it is also possible to provide the covering member 17. The rest of the configuration is the same as the above-explained embodiments. The third embodiment as well can give effects the same as the above embodiments.

In the third embodiment, the number of the off-axis targets 41 is not limited to three. It is sufficient that there be at least one. Further, the targets 41 do not have to be disk shapes and may also be ring shapes with holes at their centers.

The mechanical part comprised of the gas dispersion member 25 and the vane member 31 may also be provided in a fixed fashion. Even with this configuration, since a structure making the cathode unit side rotate is employed, the vane member 31 and the three targets 41 change in relative positions, so it is possible to selectively pass target material particles traveling from a target to the substrate.

Modifications of the third embodiment will be explained next with reference to FIGS. 10A and 10B to FIGS. 12A and 12B. In the figures, FIGS. 10A, 11A, and 12A are similar to FIG. 9 showing the front view of a cathode unit 14, while FIGS. 10B, 11B, and 12B are cross-sectional views setting cross-sections so that the characterizing parts in FIGS. 10A, 11A, and 12A are shown.

In the modification of FIGS. 10A and 10B, partition plates 46 are arranged between each two of the three targets 41 fixed to the mounting member 44. For example, when there are three targets, three partition plates are preferably arranged at equal intervals separated by angles of 120 degrees so as to surround the targets. The rest of the configuration is the same as that of the third embodiment, so substantially identical elements are assigned the same notations and explanations are omitted. In FIG. 10B, cross-sections of two adjoining cathode sets 43 and the side faces of two adjoining partition plates 46 are shown. According to this modification, the targets etc. are arranged off axis and the reactive gas is introduced from the center part of the cathode unit 14, so the partition plates 46 can prevent sputter particles from other targets from entry. This effect is similar to the effect of the third embodiment explained above. The partition plates 46 may be directly fixed to the surface of the mounting member 44 or may be fixed in a floating state.

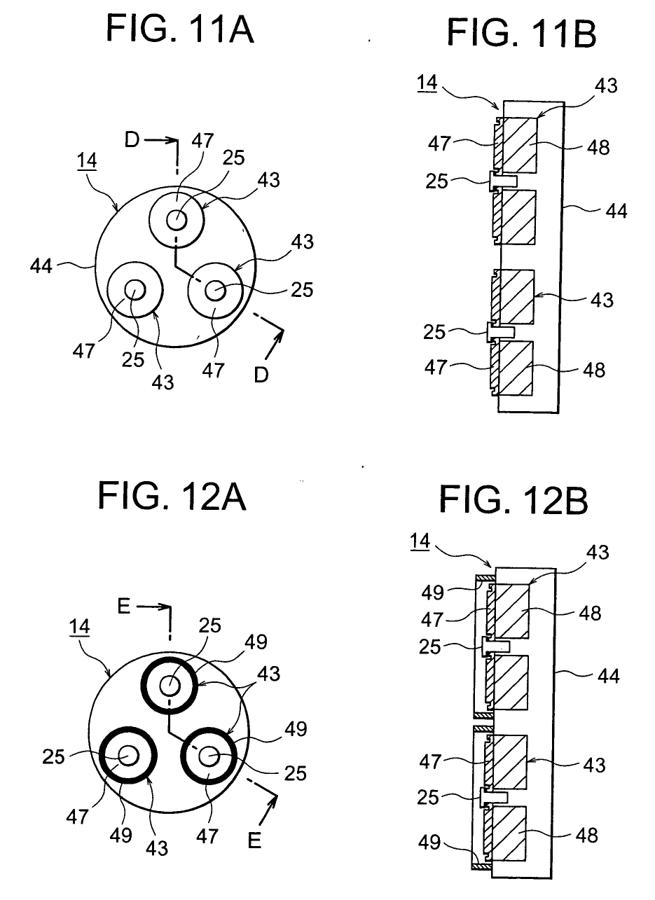

In the modification shown in FIGS. 11A and 11B, the three targets 47 fixed to the mounting member 44 are not disk shaped, but ring shaped. The mounting member 44 is not provided with a reactive gas introduction mechanism (hole and gas dispersion member) at its center like in the above embodiments. The three cathode sets 43 have ring shapes overall, have gas dispersion members 25 at their center parts, and are provided with reactive gas introduction mechanisms. FIG. 11B is a cross-sectional view along the line D-D in FIG. 11A. In this modification, the three ring shaped cathode sets 43 arranged off axis at the cathode unit 14 are provided with reactive gas introduction mechanisms at the centers of the cathode sets 43. Due to this, it is possible to introduce reactive gas from the center parts of the three targets 47 and achieve substantially the same effects as in the above embodiments.

In the modification of FIGS. 12A and 12B, provision is made the configuration shown in FIGS. 11A and 11B wherein circular partition plates 49 are provided around the targets 47 at the three cathode sets 43. FIG. 12B is a cross-section along the line E-E in FIG. 12A. The rest of the configuration is the same as that of the embodiment of FIGS. 11A and 11B, so the same elements in FIGS. 12A and 12B are assigned the same notations and explanations are omitted. In this modification, the three ring shaped cathode sets 43 arranged off axis at the cathode unit 14 are provided with reactive gas introduction mechanisms at the centers of the cathode sets 43 and are provided with partition plates 49 around the targets 47. Due to this, it is possible to introduce reactive gas from the center parts of the three targets 47 and obtain similar effects to those of the above embodiments. Further, it is possible to prevent entry of sputter particles from adjoining targets. The partition plates 49 may be directly fixed to the surface of the mounting member 44 or may be fixed in a floating state.

FIG. 13 shows a fourth embodiment of the sputtering system according to the present invention. This sputtering system is a horizontal type sputtering system. A single ring-shaped target 22 is arranged at the floor 11c of the vacuum chamber 11. Reference numeral 51 is for example a disk shaped substrate. Illustration of the support mechanism of the substrate 51 is omitted. Further, illustration of the cathode and its related parts and the vacuum evacuation system is omitted. In FIG. 13, elements substantially the same as elements explained in the above embodiments are assigned the same notations. In this sputtering system as well, a reactive gas introduction mechanism is provided at the center part of the target 22. The reactive gas introduced at this reactive gas introduction mechanism, as shown by the arrows 52, flows uniformly along the surface of the target 22 from the center part to the outer circumference and is made uniform in concentration. The reactive gas etc. are exhausted from an exhaust port 53 provided around the target 22 as shown by the arrows 54. The sputtering system according to the fourth embodiment can also give similar effects as the above embodiments.

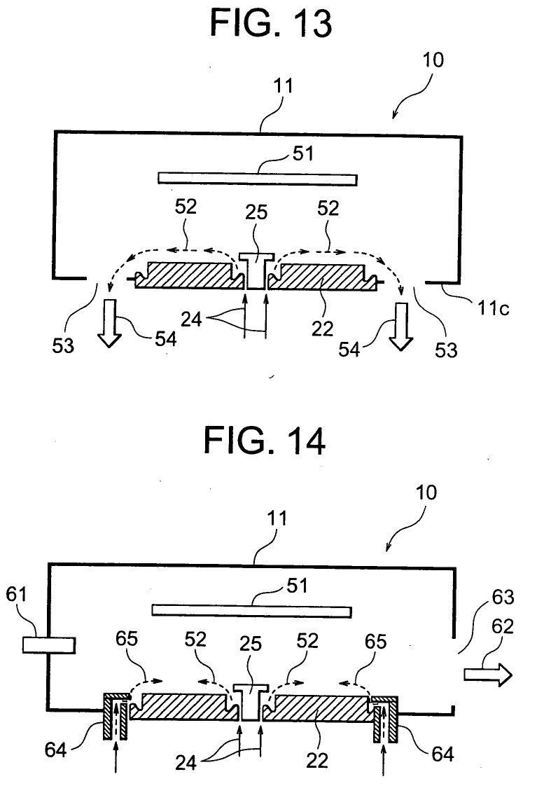

FIG. 14 shows a fifth embodiment of the sputtering system according to the present invention. The fifth embodiment is a modification of the fourth embodiment. In the fifth embodiment, elements substantially the same as elements explained in the fourth embodiment are assigned the same notations. In this embodiment, the side wall of the vacuum chamber is provided with another gas introduction part 61 and gas exhaust port 63 as shown by the arrow 62. Further, in addition to the reactive gas introduction mechanism at the center of the target 22, a reactive gas introduction mechanism 64 is provided at the entire circumference around the target 22 at the floor 11c of the vacuum chamber 11 or at several locations thereof. Reference numerals 65 show other flows of reactive gas introduced by the reactive gas introduction mechanisms 64 into the vacuum chamber and heading from the outer circumference to the center. In this case, for the reactive gas feed system, preferably common use is made of the system 23 shown in FIG. 3. Note that the exhaust port 53 provided around the target 22 explained earlier is not provided and that the gas is exhausted through the gas exhaust port 63 connected to a not shown evacuation mechanism. The rest of the configuration is the same as those of the fourth embodiment.

According to the fifth embodiment, a flow of reactive gas from the center part of the target 22 or the center part of the cathode and a flow of reactive gas from their outer circumferences are formed, so it is possible to make the concentration of reactive gas on the surface of the target uniform more effectively. Note that in the fifth embodiment, argon or another sputter gas is introduced from another gas introduction part 61 and reactive gas is introduced from the center of the target or cathode and their outer circumferences, so like in the other embodiments if introducing a gas containing the reactive gas (reactive gas or mixed gas) from at least the center of the target or cathode, it is also possible to introduce the sputter gas and auxiliary reactive gas (reactive gas other than introduced from the center) from either of the introduction parts.

Note that in the case of the fifth embodiment, the cathode is preferably made to rotate by the structure disclosed in Japanese Patent Publication (A) No. 2002-088471 by the same assignee.

In both the above fourth and fifth embodiments, in the same way as the above embodiment, it is possible to provide the covering member 17 as shown in FIG. 3, make the targets an off axis structure as shown in FIG. 9 etc., or provide a vane member 31 as shown in FIG. 7. Further, conversely, it is possible to add the characterizing configurations shown in FIG. 13A, FIG. 14A, etc. to the vertical type sputtering system of the first embodiment etc.

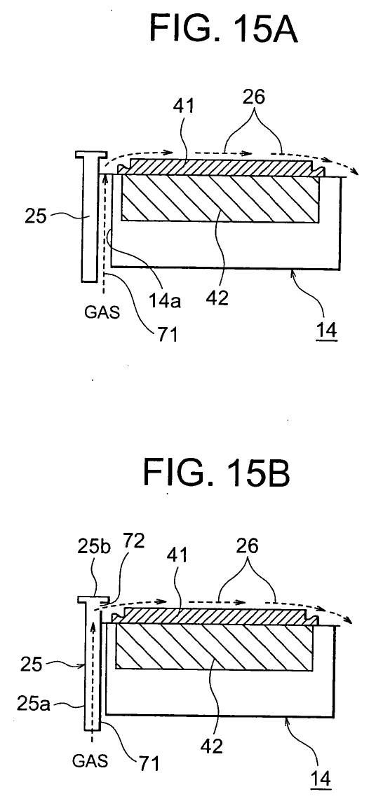

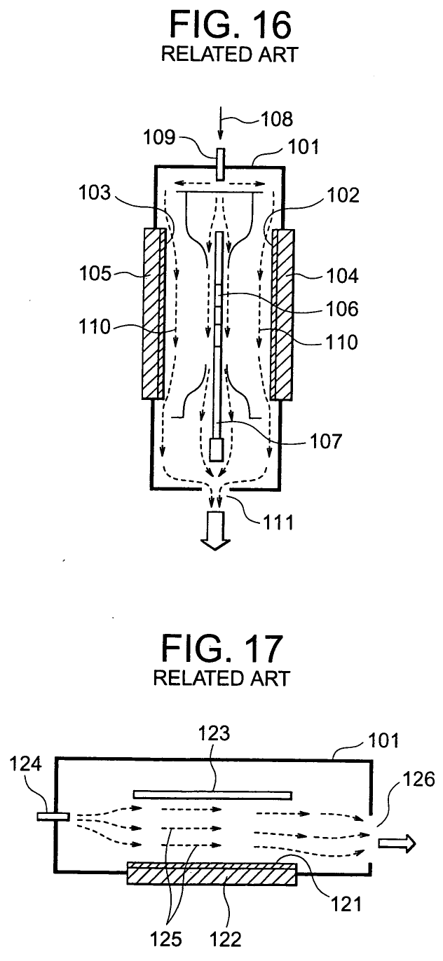

An example of the structure relating to the method of flow of the reactive gas in the above reactive gas introduction mechanism will be explained next with reference to FIGS. 15A and 15B. In the above embodiments, in principle, as shown in FIGS. 15A and 15B, provision is made of a gas dispersion member 25 passing through a hole 14a formed in each cathode unit 14. In this structure, the gap formed between the gas dispersion member 25 and the inner surface of the hole is utilized for introduction of the reactive gas 71. As opposed to this, as shown in FIG. 15B, the shaft part 25a of the gas dispersion member 25 may be formed in a pipe shape (serving as a gas pipe) and a plurality of gas outlets 72 may be formed at the base of the enlarged diameter part 25a so as to blow out the reactive gas.

In the explanation of the above embodiments, the shapes, sizes, and positional relations were shown generally to an extent enabling understanding of the present invention. The present invention is not limited to the illustrated embodiments. It may be either a two-sided sputtering system or one-sided sputtering system in each case. Further, in the two-sided sputtering system configuration of the embodiments, two cathode units were arranged at the two sides of a substrate, but the number of cathode units can be changed in accordance with the number of substrates and the process. Further, a structure causing the cathode units to rotate is also possible. In this case, the axial centers of the cathode units are utilized for provision of water pipes or electrical cables.

The present disclosure relates to subject matter contained in Japanese Patent Application No. 2003-147529, filed on May 26, 2003, the disclosure of which is expressly incorporated herein by reference in its entirety.

Although only preferred embodiments are specifically illustrated and described herein, it will be appreciated that many modifications and variations of the present invention are possible in light of the above teachings and within the purview of the appended claims without departing from the spirit and intended scope of the invention.

1. A sputtering system comprising:
a vacuum chamber having an inside into which a substrate is loaded,
at least one cathode unit provided in said vacuum chamber so as to face said substrate and including a cathode with a target,
a power source for supplying power to said cathode of said cathode unit,
a vacuum evacuation system for evacuating the inside of said vacuum chamber to a vacuum, and
a gas introduction mechanism for making reactive gas flow from a center of said cathode unit along a surface of said target to the an outer perimeter of the cathode unit,
reactive sputtering being used for sputtering of said target and deposition of a film on said substrate.

2. The sputtering system as set forth in claim 1, wherein said cathode unit is structured with the target attached to the cathode in a coaxial relationship and said reactive gas flows from a center of the target toward the outer circumference of the target along the surface of the target.

3. The sputtering system as set forth in claim 1, wherein said cathode unit is structured with a plurality of cathode sets, each of the cathode sets comprises a cathode and a target and said plurality of cathode sets are arranged off-axis around the center of said cathode unit.

4. The sputtering system as set forth in claim 1, wherein said gas introduction mechanism includes an introduction hole for introducing said reactive gas and a gas dispersion member for dispersing said introduced reactive gas.

5. The sputtering system as set forth in claim 1, further provided with a covering member surrounding a target and having a part opening toward said substrate.

6. The sputtering system as set forth in claim 1, further provided with a passage selecting means for selectively passing target material particles moving from a target to said substrate.

7. The sputtering system as set forth in claim 6, wherein said passage selecting means is provided between said target and said substrate to be able to rotate in a coaxial relationship with said substrate.

8. The sputtering system as set forth in claim 1, further provided with, along with said gas introduction mechanism for making said reactive gas flow along the surface of a target toward the outside, another gas introduction mechanism for making reactive gas flow from the outer circumference of a cathode along the surface of the target toward the inside.

9. A sputtering system comprising:
a vacuum chamber having an inside into which a substrate is loaded,
a cathode unit provided in said vacuum chamber so as to face said substrate and the cathode unit is provided with a plurality of cathode sets, each of the cathode sets is comprised of a cathode and a target,
a power source for supplying power to said cathodes of said cathode unit, and
a vacuum evacuation system for evacuating the inside of said vacuum chamber to a vacuum,
said plurality of cathode sets being arranged off-axis around a center of said cathode unit and a gas introduction mechanism is provided for making reactive gas flow from a center of each cathode set toward a periphery of each cathode set along a surface of said target.

10. The sputtering system as set forth in claim 9, wherein said gas introduction mechanism includes an introduction hole for introducing said reactive gas and a gas dispersion member for dispersing said introduced reactive gas.

11. The sputtering system as set forth in claim 9, further provided with a covering member surrounding a target and having a part opening toward said substrate.

12. The sputtering system as set forth in claim 9, further provided with a passage selecting means for selectively passing target material particles moving from a target to said substrate.

13. The sputtering system as set forth in claim 12, wherein said passage selecting means is provided between said target and said substrate to be able to rotate in a coaxial relationship with said substrate.

14. The sputtering system as set forth in claim 9, further provided with, along with said gas introduction mechanism for making said reactive gas flow along the surface of a target toward the outside, another gas introduction mechanism for making reactive gas flow from the outer circumference of a cathode along the surface of the target toward the inside.
